(19) United States
(12) Patent Application Publication
(10) Pub. No.: US 2026/0177851 A1
(43) Pub. Date: Jun. 25, 2026

(54) Display Panel and Method for Manufacturing the Same, and Display Apparatus

(71) Applicants: BEIJING BOE TECHNOLOGY DEVELOPMENT CO., LTD., Beijing (CN); BOE TECHNOLOGY GROUP CO., LTD., Chaoyang District, Beijing (CN)

(72) Inventors: Xinhong Lu, Beijing (CN); Yan Qu, Beijing (CN); Zhanfeng Cao, Beijing (CN); Shuilang Dong, Beijing (CN); Guoteng Li, Beijing (CN)

(21) Appl. No.: 18/728,959

(22) PCT Filed: Apr. 27, 2023
(86) PCT No.: PCT/CN2023/091159

§ 371 Date: Jul. 15, 2024

(51) Int. Cl. G02F 1/1333; G02F 1/1345; H05K 1/189; H10K 102/00

(52) U.S. Cl. CPC G02F 1/133345; G02F 1/1345; H05K 1/189; H10K 2102/311

(57) ABSTRACT

A display panel includes a backplane having a first main surface and a second main surface, and at least one selected side surface located therebetween, a plurality of light-emitting devices and a plurality of first connection portions disposed on the first main surface, a circuit board located on a side of the second main surface away from the first main surface, and a plurality of connection lines. Multiple first connection portions are arranged side by side in an extending direction of a selected side surface and proximate to the selected side surface. Multiple connection lines are arranged at intervals in the extending direction of the selected side surface. The plurality of connection lines are connected between the plurality of first connection portions and the circuit board, and the plurality of connection lines are attached to the at least one selected side surface.

### CROSS-REFERENCE TO RELATED APPLICATION

This application is the United States national phase of International Patent Application No. PCT/CN2023/091159, filed Apr. 27, 2023, the disclosure of which is hereby incorporated by reference in its entirety.

### BACKGROUND OF THE INVENTION

### Field of the Invention

The present disclosure relates to the field of display technologies, and in particular, to a display panel and a method for manufacturing the same, and a display apparatus.

### Description of Related Art

The display panel may include light-emitting devices. For example, in a case where the light-emitting device is a sub-millimeter light-emitting diode (mini light-emitting diode, mini LED for short) or a micro light-emitting diode (micro LED for short), the display panel has a relatively narrow frame, which is conducive to development of the display panel towards the narrow frame.

### SUMMARY OF THE INVENTION

In an aspect, a display panel is provided. The display panel includes a backplane, a plurality of light-emitting devices, a plurality of first connection portions, a circuit board and a plurality of connection lines. The backplane has a first main surface and a second main surface that are opposite, and at least one selected side surface located between the first main surface and the second main surface. The at least one selected side surface is connected to and perpendicular to the first main surface. The plurality of light-emitting devices are disposed on the first main surface. The plurality of first connection portions are disposed on the first main surface. Multiple first connection portions in the plurality of first connection portions are arranged side by side in an extending direction of a selected side surface and proximate to the selected side surface; and the extending direction of the selected side surface is parallel to the first main surface. The circuit board is located on a side of the second main surface away from the first main surface. Multiple connection lines in the plurality of connection lines are arranged at intervals in the extending direction of the selected side surface. The plurality of connection lines are connected between the plurality of first connection portions and the circuit board, and the plurality of connection lines are attached to the at least one selected side surface by attaching.

In some embodiments, the backplane further has a first transition surface; the first transition surface is connected between the selected side surface and the second main surface; a tangent plane of the first transition surface and the selected side surface have an obtuse angle therebetween, and the tangent plane of the first transition surface and the second main surface have an obtuse angle therebetween.

In some embodiments, the connection lines each include a main body portion and a second connection portion. The main body portion is at least attached to the selected side surface. The second connection portion is disposed on a side of a portion of the main body portion located on a side of the first main surface away from the second main surface, and the second connection portion is connected to a first connection portion.

In some embodiments, the second connection portion and the first connection portion are eutectic bonded.

In some embodiments, the main body portion is further attached to the second main surface.

In some embodiments, a thickness ratio of any two positions of the main body portion is in a range of 0.9 to 1.1, inclusive.

In some embodiments, a dimension of the first connection portion in a second direction is greater than or equal to 5 μm, and the second direction is a thickness direction of the backplane. A dimension of the second connection portion in a third direction is in a range of 8 μm to 12 μm, inclusive, and the third direction is a direction perpendicular to the selected side surface.

In some embodiments, the connection lines each further include a third connection portion, and the third connection portion is disposed on a side of a portion of the main body portion located on a side of the second main surface away from the first main surface.

In some embodiments, the third connection portion is connected to the circuit board.

In some embodiments, the display panel further includes a plurality of fan-out lines disposed on the second main surface. The plurality of fan-out lines are connected between a plurality of third connection portions and the circuit board.

In some embodiments, the display panel further includes a first insulating layer and a second insulating layer that are disposed sequentially. The main body portion is located between the first insulating layer and the second insulating layer. The first insulating layer has first openings each exposing the main body portion, and the second connection portion passes through a first opening to be connected to the main body portion.

In some embodiments, the first insulating layer or the second insulating layer has second openings each exposing the main body portion, and the third connection portion passes through a second opening to be connected to the main body portion.

In another aspect, a method for manufacturing a display panel is provided. The manufacturing method includes: providing a backplane, the backplane having a first main surface and a second main surface that are opposite, and at least one selected side surface located between the first main surface and the second main surface, and the at least one selected side surface being connected to and perpendicular to the first main surface; forming a plurality of first connection portions on the first main surface, multiple first connection portions in the plurality of first connection portions being arranged side by side in an extending direction of a selected side surface and proximate to the selected side surface, and the extending direction of the selected side surface being parallel to the first main surface; forming a plurality of light-emitting devices on the first main surface; providing a circuit board on a side of the second main surface away from the first main surface; and attaching a plurality of connection lines to the at least one selected side surface, multiple connection lines in the plurality of connection lines being arranged at intervals in the extending direction of the selected side surface, and the plurality of connection lines being connected between the plurality of first connection portions and the circuit board.

In some embodiments, before attaching the plurality of connection lines to the at least one selected side surface, the method further includes: forming a plurality of main body portions on a first substrate; and forming a plurality of second connection portions, the plurality of second connection portions being connected to the plurality of main body portions. Attaching the plurality of connection lines to the at least one selected side surface, includes: attaching surfaces of the plurality of main body portions away from the first substrate on the selected side surface, and the plurality of first connection portions being connected to the plurality of second connection portions; and removing the first substrate.

In some embodiments, before forming the plurality of main body portions on the first substrate, the method further includes: forming a second insulating layer on the first substrate. After forming the plurality of main body portions on the first substrate, and before forming the second connection portions, the method further includes: forming a first insulating layer on a side of the plurality of main body portions away from the substrate; and forming a plurality of first openings in the first insulating layer exposing the plurality of main body portions. Forming the second connection portions, includes: forming the plurality of second connection portions in the plurality of first openings.

In some embodiments, before forming the second insulating layer on the first substrate, the method further includes: forming a plurality of third connection portions on the first substrate. After forming the second insulating layer on the first substrate, and before forming the first insulating layer on the side of the plurality of main body portions away from the second insulating layer, the method further includes: forming a plurality of second openings in the second insulating layer exposing the plurality of third connection portions. Forming the plurality of main body portions on the first substrate, includes: forming the plurality of main body portions on the second insulating layer and in the plurality of second openings exposing the plurality of third connection portions, the plurality of main body portions being connected to the plurality of third connection portions.

In some embodiments, after forming the plurality of main body portions on the first substrate, and before forming the second connection portions, the method further includes: forming a plurality of second openings in the first insulating layer exposing the plurality of main body portions. After forming the plurality of second openings, the method further includes: forming a plurality of third connection portions in the plurality of second openings, the plurality of main body portions being connected to the plurality of third connection portions.

In some embodiments, before providing the circuit board on the side of the second main surface away from the first main surface, the method further includes: forming a plurality of fan-out lines on the second main surface, the plurality of fan-out lines being connected to the plurality of third connection portions. Providing the circuit board on the side of the second main surface away from the first main surface, includes: bonding the circuit board to ends of the plurality of fan-out lines away from the plurality of third connection portions.

In some embodiments, before forming the plurality of main body portions on the first substrate, the method further includes: forming a peelable layer on the first substrate. Removing the first substrate includes: peeling off the peelable layer.

In yet other aspect, a display apparatus is provided. The display apparatus includes the above display pane.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments;

FIG. 2 is a top view of a display panel, in accordance with some embodiments;

FIG. 3 is a bottom view of a display panel, in accordance with some embodiments;

FIG. 4 is a front view of a display apparatus, in accordance with some embodiments;

FIG. 5 is a front view of a display panel in the related art;

FIGS. 6 to 8 are each a structural diagram of a first connection portion, in accordance with some embodiments;

FIGS. 9 and 10 are each a structural diagram of a second connection portion, in accordance with some embodiments;

FIG. 11 is a structural diagram of a connection line, in accordance with some embodiments;

FIG. 12 is a front view of a display panel, in accordance with some embodiments;

FIG. 13 is a structural diagram of another connection line, in accordance with some embodiments;

FIG. 14 is a bottom view of another display panel, in accordance with some embodiments;

FIG. 15 is a front view of another display panel, in accordance with some embodiments;

FIG. 16 is a flow diagram of a method for manufacturing a display panel, in accordance with some embodiments;

FIGS. 17 to 22 are process diagrams of forming a connection line, in accordance with some embodiments;

FIGS. 23 to 26 are process diagrams of manufacturing a display panel, in accordance with some embodiments;

FIGS. 27 to 30 are process diagrams of forming another connection line, in accordance with some embodiments;

FIGS. 31 to 34 are process diagrams of manufacturing another display panel, in accordance with some embodiments;

FIGS. 35 to 41 are process diagrams of forming another connection line, in accordance with some embodiments; and

FIGS. 42 and 43 are process diagrams of manufacturing another display panel, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude apparatuses that are applicable to or configured to perform additional tasks or steps.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of areas are enlarged for clarity. Variations in shapes relative to the accompanying drawings due to, for example, manufacturing technologies and/or tolerances may be envisaged. Therefore, the exemplary embodiments should not be construed to be limited to the shapes of areas shown herein, but to include deviations in the shapes due to, for example, manufacturing. For example, an etched area shown in a rectangular shape generally has a feature of being curved. Therefore, the areas shown in the accompanying drawings are schematic in nature, and their shapes are not intended to show actual shapes of the areas in an apparatus, and are not intended to limit the scope of the exemplary embodiments.

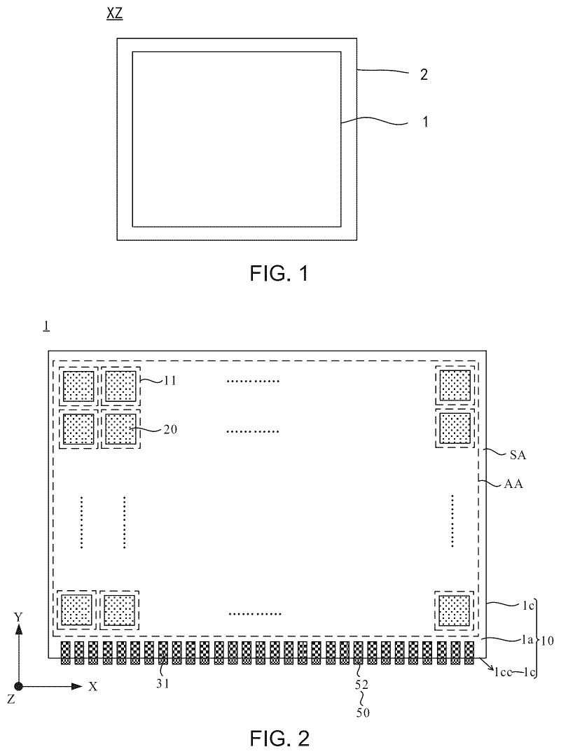

Some embodiments of the present disclosure provide a display apparatus. Referring to FIG. 1, the display apparatus XZ is a product having a function of displaying images (including an image in stationary or an image in motion (which may be a video)). The display apparatus XZ may be, for example, a virtual reality (VR) display device or an augmented reality (AR) display device. Alternatively, the display apparatus XZ may be, for example, a display, a mobile phone, a tablet computer (pad), a netbook, a television, a personal digital assistant (PDA), an ultra-mobile personal computer (UMPC), a netbook, a wearable device (e.g., smart watch) or a vehicle-mounted display apparatus. The embodiments do not limit the type of the display apparatus XZ.

The display apparatus XZ includes a display panel 1, and may further include a controller, a frame 2 (e.g., a middle frame), and the like. The frame 2 is configured to fix the display panel 1, the controller, and the like. The controller is configured to send image data (e.g., grayscale data) to the display panel 1, and may be, for example, a central processing unit (CPU) or a graphics processing unit (GPU). The display panel 1 is configured to receive data signals (e.g., voltage signals) corresponding to the image data, and to display an image (i.e., a picture) based on the data signals. As shown in FIG. 2, the display panel 1 may have a display area AA and a non-display area SA. The display area AA of the display panel 1 is an area of the display panel 1 on which an image can be displayed. An area of the display panel 1 other than the display area AA is the non-display area SA. The non-display area SA may be located on at least one side (e.g., one side or multiple sides) of the display area AA. For example, the non-display area SA surrounds the display area AA.

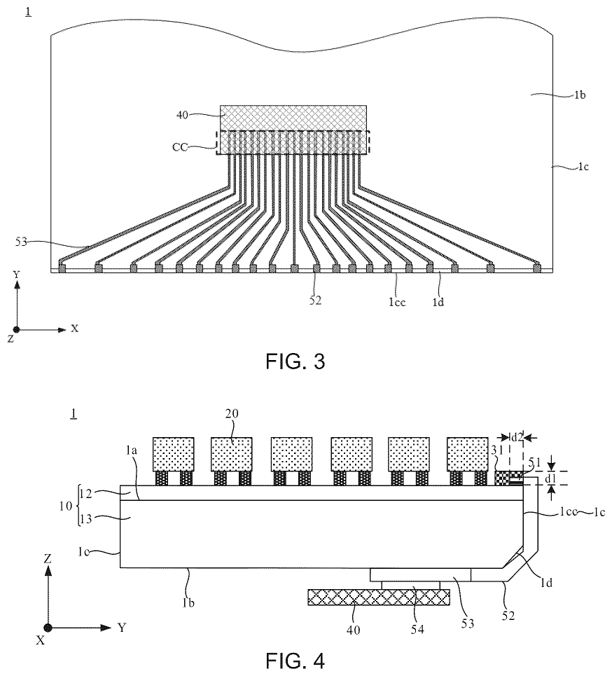

Referring to FIGS. 2 to 4, the display panel 1 includes a plurality of sub-pixels 11 located in the display area AA. For example, the plurality of sub-pixels 11 include first sub-pixels for emitting light of a first color, second sub-pixels for emitting light of a second color, and third sub-pixels for emitting light of a third color. The first color, the second color and the third color are three primary colors (e.g., red, green and blue). For example, the display panel 1 may include red sub-pixels, green sub-pixels and blue sub-pixels.

The display apparatus further includes a plurality of signal lines, such as a plurality of gate lines and a plurality of data lines. Each sub-pixel 11 may be coupled to a gate line and a data line, and is configured to write a data signal transmitted by the data line in response to a scan signal transmitted by the gate line, and emit light with corresponding intensity based on the data signal. The plurality of gate lines may extend in a first direction X. A (e.g., each) gate line may be coupled to sub-pixels 11 in the same row, and is configured to transmit a scan signal to the sub-pixels 11 in the same row. The plurality of data lines may extend in a third direction Y. A (e.g., each) data line may be coupled to sub-pixels 11 in the same column, and is configured to provide a data signal to the sub-pixels 11 in the same column.

The display panel 1 includes a backplane 10. The backplane 10 has a first main surface 1a and a second main surface 1b that are opposite, and at least one (e.g., one, two, or four) selected side surface 1cc located between the first main surface 1a and the second main surface 1b. For example, the display panel 1 has a display side and a non-display side that are opposite. The display side is a side of the display panel 1 that can display images. The first main surface 1a may be a surface of the backplane 10 corresponding to the display side, and the second main surface 1b may be a surface of the backplane 10 corresponding to the non-display side. The first main surface 1a and the second main surface 1b may be rectangular in shape.

For example, the backplane 10 further has a plurality of first side surfaces 1c each located between the first main surface 1a and the second main surface 1b, and at least one first side surface 1c in the plurality of first side surfaces 1c may be a selected side surface 1cc. In some examples, the number of the first side surfaces 1c is four, and at least one first side surface 1c in the four first side surfaces 1c may be the selected side surface 1cc. For example, a first side surface 1c in the four first side surfaces 1c may be a selected side surface 1cc. As another example, two first side surfaces 1c in the four first side surfaces 1c may be selected side surfaces 1cc. As another example, four first side surfaces 1c in the four first side surfaces 1c may be selected side surfaces 1cc. In some examples, the plurality of first side surfaces 1c are connected to and perpendicular to the first main surface 1a.

For example, the backplane 10 may include a substrate 13 and a driving circuit layer 12 that are stacked. In this case, the first main surface 1a may be a surface of the substrate 13 proximate to the driving circuit layer 12, and the second main surface 1b may be a surface of the substrate 13 away from the driving circuit layer 12. The driving circuit layer 12 includes, for example, thin film transistors (TFTs) or a micro driver chip, a plurality of signal lines (e.g., the gate lines and the data lines as mentioned above), and other structures. For example, the material of the substrate 13 may be made of glass, quartz or plastic.

The display panel 1 further includes a plurality of light-emitting devices 20 disposed on the first main surface 1a. For example, the plurality of light-emitting devices 20 may be disposed on the driving circuit layer 12. The plurality of light-emitting devices 20 may be located in the display area AA of the display panel 1. The driving circuit layer 12 is coupled to the plurality of light-emitting devices 20, and configured to drive the plurality of light-emitting devices 20 to emit light.

The light-emitting device 20 may include an organic light-emitting diode (OLED), a quantum dot light-emitting diode (QLED), a mini light-emitting diode (mini LED) or a micro light-emitting diode (micro LED).

The display panel 1 further includes a circuit board 40, a plurality of first connection portions 31 and a plurality of connection lines 50.

Multiple first connection portions 31 are arranged side by side in an extending direction of a selected side surface 1cc, and the extending direction of the selected side surface 1cc is parallel to the first main surface 1a. For example, in a case where there is one or two selected side surfaces 1cc, an extending direction of each selected side surface 1cc may be parallel to the first direction X; that is, the extending direction of each selected side surface 1cc is parallel to the extending direction of the gate lines. As another example, in a case where there are four selected side surfaces 1cc, an extending direction of each selected side surface 1cc may be understood as a direction along a rectangular ring shape. In some examples, the plurality of first connection portions 31 are arranged at intervals in the first direction X.

The plurality of first connection portions 31 are provided proximate to the selected side surface(s) 1cc. For example, the first connection portion 31 has a second side surface, the second side surface is coplanar with the selected side surface 1cc, and the second side surface is a side surface of the first connection portion 31 closest to the selected side surface 1cc. Multiple connection lines 50 are arranged at intervals in the extending direction of the selected side surface 1cc. In some examples, in the first direction X, a space between adjacent connection lines 50 is equal to a space between adjacent first connection portions 31.

The circuit board 40 is located on a side of the second main surface 1b away from the first main surface 1a. The plurality of first connection portions 31 are disposed on the first main surface 1a. For example, the plurality of first connection portions 31 may be located in the non-display area SA of the display panel 1. For example, the plurality of first connection portions 31 may be provided in the driving circuit layer 12. In this way, a circuit structure is formed on the first main surface 1a through an array process. The circuit structure includes, for example, the plurality of formed first connection portions 31, and the circuit structure may further include, for example, the plurality of formed signal lines (e.g., the gate lines and the data lines). The plurality of connection lines 50 are used to be connected between the plurality of first connection portions 31 and the circuit board 40. In some examples, the plurality of first connection portions 31 are connected to the plurality of light-emitting devices 20. For example, the plurality of first connection portions 31 are connected to the plurality of light-emitting devices 20 by a plurality of signal lines (e.g., the data lines). The circuit board 40 is configured to generate corresponding electrical signals (e.g., the data signals) based on the image data output by the above controller, and the electrical signals (e.g., the data signals) may control the luminous intensity of the light-emitting devices 20. The circuit board 40 may be, for example, a flexible circuit board 40.

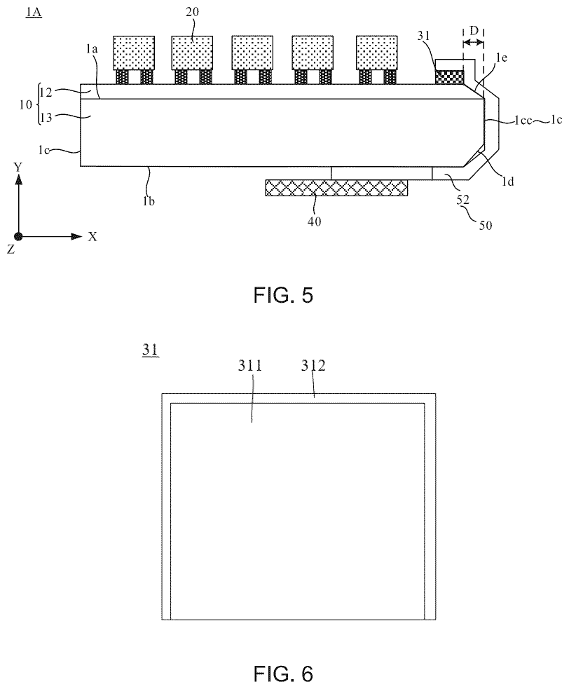

In the related art, referring to FIG. 5, in order to realize a narrow frame of a display panel 1A, the first connection portions 31 are located on the first main surface 1a, the circuit board 40 is located on the second main surface 1b, and a plurality of connection lines 50 connect the first connection portions 31 to the circuit board 40. The process for manufacturing the connection lines 50 mainly includes a coating process. For the coating process, a metal coating layer is formed by a film formation method such as sputtering, and then the metal coating layer is divided into the plurality of connection lines 50 by etching (e.g., laser etching). The connection line 50 extends from the first main surface 1a to the second main surface 1b through the selected side surface 1cc. An end of the connection line 50 is connected to the first connection portion 31, and another end of the connection line 50 is connected to the circuit board 40. However, in order to prevent the connection line 50 from being broken at a corner (which may be called a first corner, and an angle of the first corner is less than or equal to 90°) formed between the selected side surface 1cc and the first main surface 1a, a second transition surface 1e is used to be connected between the first main surface 1a and the selected side surface 1cc, so that the second transition surface 1e and the first main surface 1a have an obtuse angle therebetween, and the second transition surface 1e and the selected side surface 1cc have an obtuse angle therebetween, which may prevent the connection line 50 from being broken. The provision of the second transition surface 1e makes the frame of the display panel 1A wider, for example, an increased width of the frame is D.

With continued reference to FIGS. 2 to 4, the selected side surface 1cc is connected to the first main surface 1a, that is, the selected side surface 1cc is in contact with the first main surface 1a. Moreover, the selected side surface 1cc is perpendicular to the first main surface 1a, that is, the angle of the first corner formed between the selected side surface 1cc and the first main surface 1a is 90°. Compared with the display panel 1A in the related art, the display panel 1 in the present embodiments removes the second transition surface 1e in the related art, so as to make the frame of the display panel 1 narrower, which is conducive to development of the display panel 1 towards the narrow frame. In addition, the plurality of connection lines 50 are attached to the selected side surface(s) 1cc by attaching. That is, the plurality of formed connection lines 50 are attached to the selected side surface(s) 1cc using adhesive or the like, thereby increasing reliability of the plurality of connection lines 50. In addition, compared with a case where the connection lines 50 are formed on the selected side surface 1cc of the display panel 1A by using the coating process in the related art, in the present embodiments, the formed connection lines 50 are attached to the selected side surface(s) 1cc, and thus the problem of low yield rate the connection lines caused by processing in the related art may be solved.

In the present embodiments, when a plurality of display panels 1 are tiled, since the frames of the display panels 1 become narrow, a gap between adjacent display panels 1 (or display apparatus) also decrease after adjacent display panels 1 (or display apparatus) are tiled. For example, when the plurality of display panels 1 are tiled, a distance between adjacent display panels 1 in the present embodiments is smaller than a distance between adjacent display panels 1A in the related art. For example, the distance between the adjacent display panels 1 in the present embodiments is reduced by 2 times D than the distance between the adjacent display surfaces 1A in the related art.

In some embodiments, the connection lines 50 each includes a main body portion 52 and a second connection portion 51. The second connection portion 51 is disposed on a side of a portion of the main body portion 52 located on a side of the first main surface 1a away from the second main surface 1b. In this way, the second connection portion 51 is used to be connected to the first connection portion 31. The main body portion 52 is attached to the selected side surface 1cc but not attached to the first main surface 1a, so that the main body portion 52 is not bent at the first corner, thereby preventing the plurality of connection lines 50 from being broken at the first corner, and further increasing the reliability of the main body portions 52.

For example, the second connection portion 51 and the first connection portion 31 are connected by eutectic bonding. For example, a preset temperature (e.g., greater than 400 degrees celsius) and a predetermined pressure (e.g., 5 kN to 100 kN) are applied to a position of the second connection portion 51 and the first connection portion 31 for a certain period of time (e.g., 5 s to 10 s), so that the second connection portion 51 and the first connection portion 31 form eutectic bonding, and thus the second connection portion 51 is connected to the first connection portion 31. In some examples, the second connection portion 51 and the second side surface of the first connection portion 31 are in contact and connected by eutectic bonding.

In some examples, as shown in FIG. 4, a dimension d1 of the first connection portion 31 in a second direction Z is greater than or equal to 5 μm (e.g., 5 μm, 6 μm, 7 μm, 8 μm, 9 μm, 10 μm, 11 μm or 12 μm). As a result, when the second connection portion 51 and the first connection portion 31 are eutectic bonded, there is sufficient tolerance for positional deviation, thereby increasing the reliability of the connection between the first connection portion 31 and the second connection portion 51. The second direction Z is a thickness direction of the backplane 10. A dimension d2 of the second connection portion 51 in the third direction Y is in a range of 8 μm to 12 μm, inclusive. As a result, the second connection portion 51 and the first connection portion 31 have a relatively great bonding force after eutectic bonding, thereby increasing the reliability of the connection between the first connection portion 31 and the second connection portion 51. The third direction Y is a direction perpendicular to the selected side surface 1cc. A dimension of the main body portion 52 in the third direction Y is greater than or equal to 2 μm.

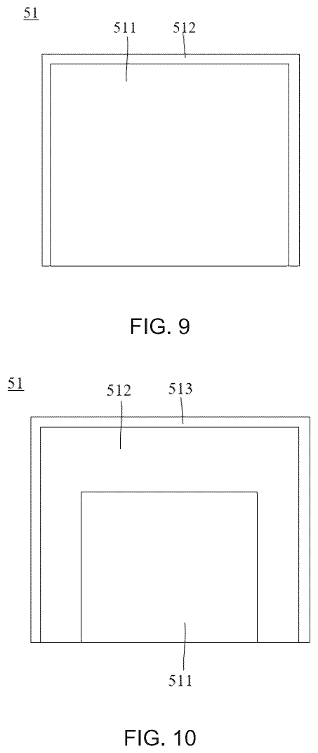

In some examples, referring to FIG. 6, the first connection portion 31 includes a first conductive layer 311 and a first protective layer 312, and the first protective layer 312 wraps the first conductive layer 311. The first conductive layer 311 and the first protective layer 312 are both made of metal. The melting point of the first conductive layer 311 is greater than the melting point of the first protective layer 312. Referring to FIG. 9, the second connection portion 51 includes a second conductive layer 511 and a second protective layer 512, and the second protective layer 512 wraps the second conductive layer 511. The second conductive layer 511 and the second protective layer 512 are both made of metal. The melting point of the second conductive layer 511 is greater than the melting point of the second protective layer 512. For example, the melting points of the first conductive layer 311 and the second conductive layer 511 are both greater than the melting point of the first protective layer 312, and the melting points of the first conductive layer 311 and the second conductive layer 511 are both greater than the melting point of the second protective layer 512.

The first conductive layer 311 and the second conductive layer 511 may be made of metal elements. For example, the metal element may be copper. Alternatively, the first conductive layer 311 and the second conductive layer 511 may be made of metal alloys. For example, the metal alloy may be an alloy of the above metal element. The materials of the first protective layer 312 and the second protective layer 512 may be metal elements. For example, the metal element may be nickel or tin. The materials of the first protective layer 312 and the second protective layer 512 may be metal alloys. For example, the metal alloy is an alloy of any of the above metal elements (e.g., copper alloy or nickel alloy).

The principle of eutectic bonding between the first connection portion 31 and the second connection portion 51 is as follows, At a preset temperature, the first conductive layer 311 and the second conductive layer 511 undergo eutectic melting to become liquid and form a primary bonding pattern, and the first protective layer 312 and the second protective layer 512 undergo eutectic melting to become liquid and form a first supplementary bonding pattern. Since the melting point of the first conductive layer 311 is greater than the melting point of the first protective layer 312, and the melting point of the second conductive layer 511 is greater than the melting point of the second protective layer 512, during cooling, the first conductive layer 311 and the second conductive layer 511 will freeze, and then the first protective layer 312 and the second protective layer 512 freeze. In a case where the primary bonding pattern is in a solid state and the first supplementary bonding pattern is in a liquid state, due to connection between the primary bonding pattern and the first supplementary bonding pattern, the liquid first supplementary bonding pattern may flow into voids in the solid primary bonding pattern, thereby filling the voids in the solid primary bonding pattern. As the temperature continues to decrease, the first supplementary bonding pattern freezes to be in the solid state. In this case, both the primary bonding pattern and the first supplementary bonding pattern are both in solid states. Then, during eutectic bonding, the voids in the primary bonding pattern are filled with the first supplementary bonding pattern, so that gas tightness and stability of bonding of the primary bonding pattern may be improved.

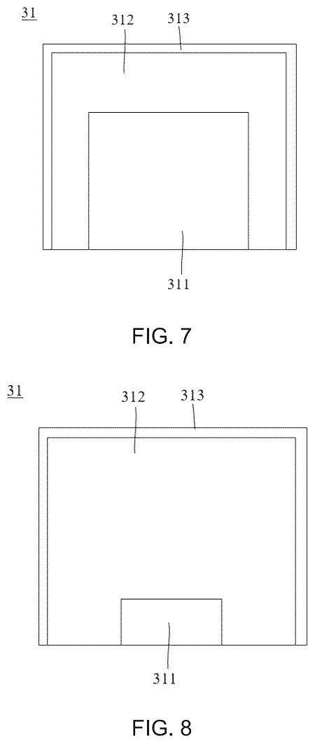

In a possible implementation, referring to FIGS. 7 and 8, the first connection portion 31 further includes a third protective layer 313, and the third protective layer 313 wraps the first protective layer 312. Referring to FIG. 10, the second connection portion 51 further includes a fourth protective layer 513, and the fourth protective layer 513 wraps the second protective layer 512. The materials of the third protective layer 313 and the fourth protective layer 513 are both metal, the melting point of the first protective layer 312 is greater than the melting point of the third protective layer 313, and the melting point of the second protective layer 512 is greater than the melting point of the fourth protective layer 513. For example, the materials of the third protective layer 313 and the fourth protective layer 513 are both gold.

During the eutectic bonding between the first connection portion 31 and the second connection portion 51, at the preset temperature, the third protective layer 313 and the fourth protective layer 513 undergo eutectic melting to become liquid and form a second supplementary bonding pattern. The second supplementary bonding pattern may fill the voids in the primary bonding pattern and voids in the first supplementary bonding pattern, thereby improving the gas tightness and stability of the primary bonding pattern and the first supplementary bonding pattern.

A volume ratio of the first conductive layer 311 to the first protective layer 312 is less than or equal to 1. For example, the volume ratio of the first conductive layer 311 to the first protective layer 312 shown in FIG. 7 is equal to 1, and the volume ratio of the first conductive layer 311 to the first protective layer 312 shown in FIG. 8 is less than 1. A volume ratio of the second conductive layer 511 to the second protective layer 512 is less than or equal to 1. For example, the volume ratio of the second conductive layer 511 to the second protective layer 512 shown in FIG. 10 is equal to 1.

As another example, the second connection portion 51 and the first connection portion 31 are soldered using solder (e.g., tin solder).

Examples of two display panels are provided below.

### EXAMPLE 1

With continued reference to FIGS. 2 to 4, the backplane 10 further has a first transition surface 1d. The first transition surface 1d is connected between the selected side surface 1cc and the second main surface 1b. In the related art, since the connection lines 50 are formed by using the coating process, a thickness of the main body portion 52 near the first transition surface 1d is smaller than a thickness of the connection lines 50 at the selected side surface 1cc, so that the connection line 50 has lower reliability. In the present embodiments, the formed main body portion 52 is attached to the first transition surface 1d, so that the main body portion 52 has approximately equal thickness at different positions.

Since a tangent plane of the first transition surface 1d and the selected side surface 1cc have an obtuse angle therebetween, and the tangent plane of the first transition surface 1d and the second main surface 1b have an obtuse angle therebetween, the main body portion 52 is also attached to the second main surface 1b. It can be understood that the main body portion 52 extends from the selected side surface 1cc to the second main surface 1b through the first transition surface 1d and is attached to the second main surface 1b. As a result, the main body portion 52 has a small bending angle at the first transition surface 1d, thereby solving the problem of the main body portion 52 breaking due to bending at the first transition surface 1d.

In some examples, the first transition surface 1d may be an inclined plane, and thus the tangent plane of the first transition surface 1d is the inclined plane. In some other examples, the first transition surface 1d may be an outwardly convex curved surface, for example, the curved surface may be an outwardly convex quarter cylinder surface.

For example, a thickness ratio of any two positions of the main body portion 52 is in a range of 0.9 to 1.1, inclusive (e.g., 0.9, 1 or 1.1). Therefore, the formed main body portion 52 has substantially equal thickness at any position, thereby increasing the reliability of the main body portion 52. In some examples, a thickness ratio of any two positions of one of the selected side surface 1cc, the first transition surface 1d and the second main surface 1b is in a range of 0.9 to 1.1, inclusive. In some other examples, a thickness ratio of any two of a thickness of the main body portion 52 at the selected side surface 1cc, a thickness of the main body portion 52 at the first transition surface 1d, and a thickness of the main body portion 52 at the second main surface 1b is in a range of 0.9 to 1.1, inclusive. The thickness of the main body portion 52 at the selected side surface 1cc may be understood as an average thickness of the main body portion 52 at the selected side surface 1cc, and may also be understood as a thickness of the main body portion 52 at the center position of the selected side surface 1cc. For the description of the thickness of the main body portion 52 at the first transition surface 1d and the thickness of the main body portion 52 at the second main surface 1b, reference may be made to the related description of the thickness of the main body portion 52 at the selected side surface 1cc.

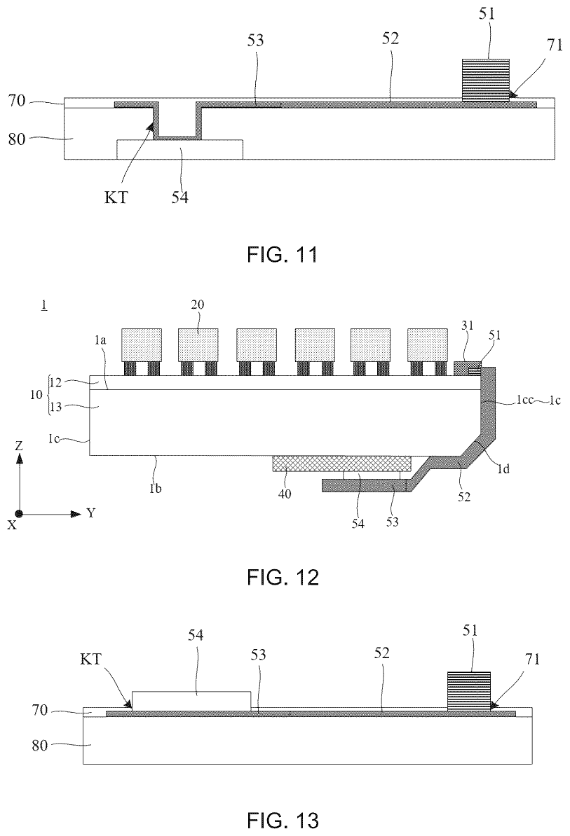

The display panel 1 further includes a first insulating layer 70 and a second insulating layer 80 that are disposed sequentially. The main body portion 52 is located between the first insulating layer 70 and the second insulating layer 80. The first insulating layer 70 has first openings 71 each exposing the main body portion 52, and the second connection portion 51 passes through the first opening 71 to be connected to the main body portion 52. For example, in the third direction Y, a dimension of the second insulating layer 80 is in a range of 3 μm to 20 μm, inclusive (e.g., 3 μm, 5 μm, 7 μm, 10 μm, 13 μm, 15 μm, 17 μm or 20 μm). Thus, the second insulating layer 80 may protect the main body portion 52, and may also prevent the frame from being too thick caused by an excessively thick second insulating layer 80. A material of the first insulation layer 70 may be an inorganic material such as silicon nitride or silicon oxide. The second insulating layer 80 may be made of polyimide or the like. A right surface of the second insulating layer 80 shown in FIG. 11 is flush with an upper surface of the first connection portion 31, and may be used as a processing reference.

For example, the connection line 50 further includes third connection portions 54. The plurality of third connection portions 54 are each provided on a side of a portion of the main body portion 52 located on a side of the second main surface 1b away from the first main surface 1a. The plurality of third connection portions 54 are bonded to the bonding area of the circuit board 40. The material of the third connection portion 54 may be a metal material. For example, the metal material may be a metal element such as copper, aluminum, or gold; alternatively, the metal material may be an alloy of any of the above metal elements.

In some examples, with continued reference to FIGS. 2 to 4 and 11, the second insulating layer 80 has a plurality of second openings KT respectively exposing a plurality of main body portions 52. A third connection portion 54 passes through a second opening KT to be connected to a main body portion 52. In this case, the first insulating layer 70 is pasted on the selected side surface 1cc, the first transition surface 1d and the second main surface 1b using an adhesive layer, and the circuit board 40 is not pasted on the second main surface 1b.

In some other examples, the first insulating layer 70 has a plurality of second openings KT respectively exposing a plurality of main body portions 52. A third connection portion 54 passes through a second opening KT to be connected to a main body portion 52. In this case, the first insulating layer 70 is pasted on the selected side surface 1cc, the first transition surface 1d and the second main surface 1b using an adhesive layer, and the circuit board 40 is also pasted on the second main surface 1b using another adhesive layer.

In a possible implementation, referring to FIGS. 11 and 12, the display panel 1 further includes a plurality of fan-out lines 53. The plurality of fan-out lines 53 are also located between the first insulating layer 70 and the second insulating layer 80. The plurality of fan-out lines 53 are respectively connected to the plurality of main body portions 52. A third connection portion 54 is connected to a fan-out line 53 through a second opening KT. The plurality of fan-out lines 53 may be located on a side of the second main surface 1b away from the first main surface 1a.

### EXAMPLE 2

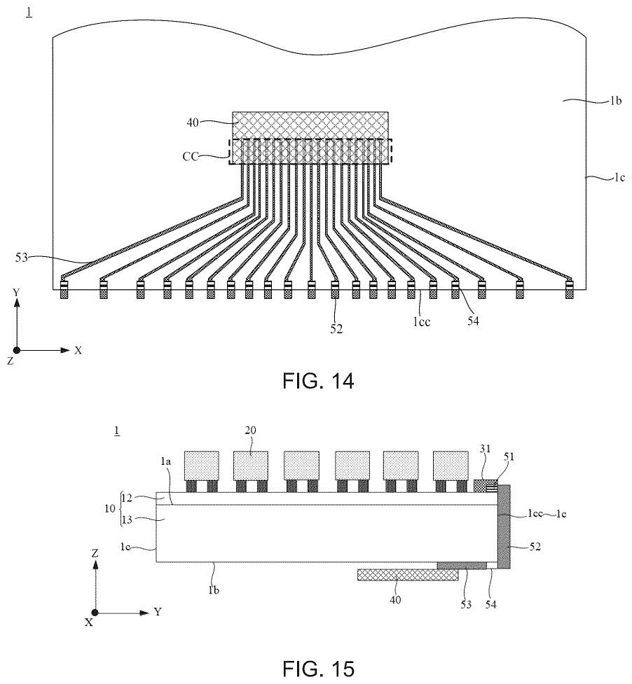

Referring to FIGS. 2, 14 and 15, the selected side surface 1cc is connected to the second main surface 1b, that is, the selected side surface 1cc is in contact with the second main surface 1b, and the selected side surface 1cc is perpendicular to the second main surface 1b. In order to prevent the main body portion 52 from being broken at the corner (which may be called a second corner, and an angle of the second corner is equal to 90°) formed between the selected side surface 1cc and the second main surface 1b, the main body portion 52 may not be attached to the second main surface 1b. That is, the third connection portion 54 is used to be connected to the circuit board 40. The plurality of third connection portions 54 are each provided on a side of a portion of the main body portion 52 located on a side of the second main surface 1b away from the first main surface 1a.

For example, the plurality of fan-out lines 53 are disposed on the second main surface 1b, that is, the plurality of fan-out lines 53 are not provided between the first insulating layer 70 and the second insulating layer 80 shown in FIG. 13. In this case, the main body portion 52 is located between the first insulating layer 70 and the second insulating layer 80. The plurality of fan-out lines 53 are respectively connected to the plurality of third connection portions 54. The plurality of fan-out lines 53 are bonded to the bonding area CC of the circuit board 40. In some examples, a third insulating layer is provided on the second main surface 1b, and the plurality of fan-out lines 53 are located between the second main surface 1b and the third insulating layer. That is, the third insulating layer covers the plurality of fan-out lines 53 disposed on the second main surface 1b. The third insulating layer is provided therein with a plurality of third holes and a plurality of fourth holes that expose both ends of each of the plurality of fan-out lines 53. The plurality of third connection portions 54 are connected to the plurality of fan-out lines 53 through the plurality of third holes, and the circuit board 40 is bonded to the plurality of fan-out lines 53 through the plurality of fourth holes.

For example, in the second direction Z, a distance between the second connection portion 51 and the third connection portion 54 is greater than or equal to the thickness of the backplane 10.

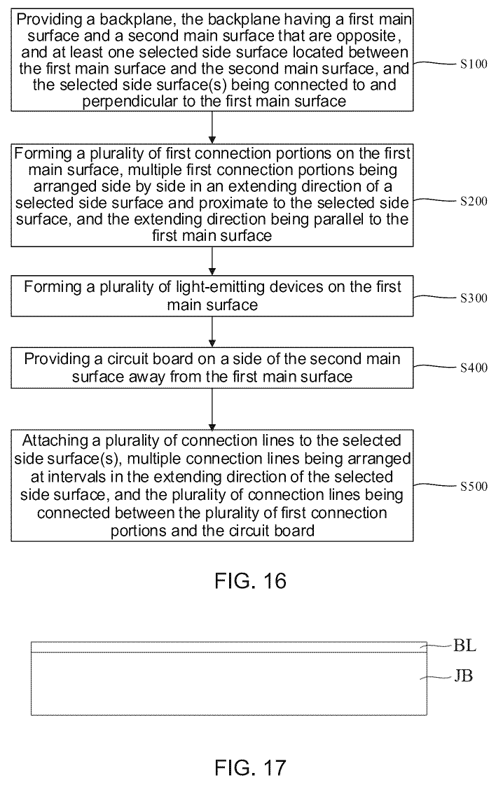

Embodiments of the present disclosure further provide a method for manufacturing the display panel. The manufacturing method includes the following steps S100 to 500. Referring to FIG. 16, in step S100, a backplane 10 is provided, where the backplane 10 has a first main surface 1a and a second main surface 1b that are opposite, and at least one selected side surface 1cc located between the first main surface 1a and the second main surface 1b; and the selected side surface(s) 1cc are connected to and perpendicular to the first main surface 1a. In step S200, a plurality of first connection portions 31 are formed on the first main surface 1a, where multiple first connection portions 31 are arranged side by side in an extending direction of a selected side surface 1cc and proximate to the selected side surface 1cc, and the extending direction of the selected side surface 1cc is parallel to the first main surface 1a. In step S300, a plurality of light-emitting devices are formed on the first main surface 1a. In step S400, a circuit board 40 is provided on a side of the second main surface 1b away from the first main surface 1a. In step S500, a plurality of connection lines are attached to the selected side surface(s) 1cc, where multiple connection lines are arranged at intervals in the extending direction of the selected side surface 1cc, and the plurality of connection lines are connected between the plurality of first connection portions 31 and the circuit board 40.

For descriptions and effects of the step S100, the step S200, the step S300, the step S400 and the step S500, reference may be made to the relevant description of the above display panel, and details are not repeated. In some examples, the step S500 may be performed, and then the step S400 may be performed.

In some embodiments, before attaching the plurality of connection lines to the selected side surface(s) 1cc, the method further includes: forming a plurality of main body portions 52 on a first substrate JB; and forming a plurality of second connection portions 51, the plurality of second connection portions 51 being connected to the plurality of main body portions 52. In the step S500, the plurality of main body portions 52 (i.e., a whole of the plurality of main body portions 52 and the first substrate) are attached to the selected side surface(s) 1cc; and the plurality of second connection portions 51 are connected to the plurality of first connection portions 31, for example, the plurality of second connection portions 51 are connected to the plurality of first connection portions 31 by eutectic bonding. After attaching the plurality of connection lines to the selected side surface(s) 1cc, the method further includes: removing the first substrate JB. The material of the first substrate JB may be glass or the like.

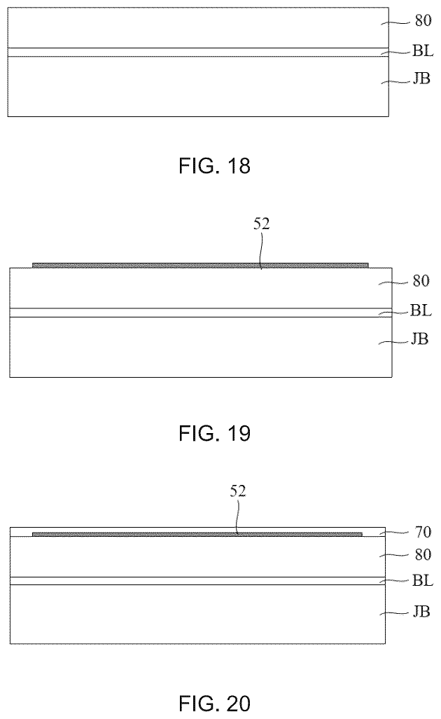

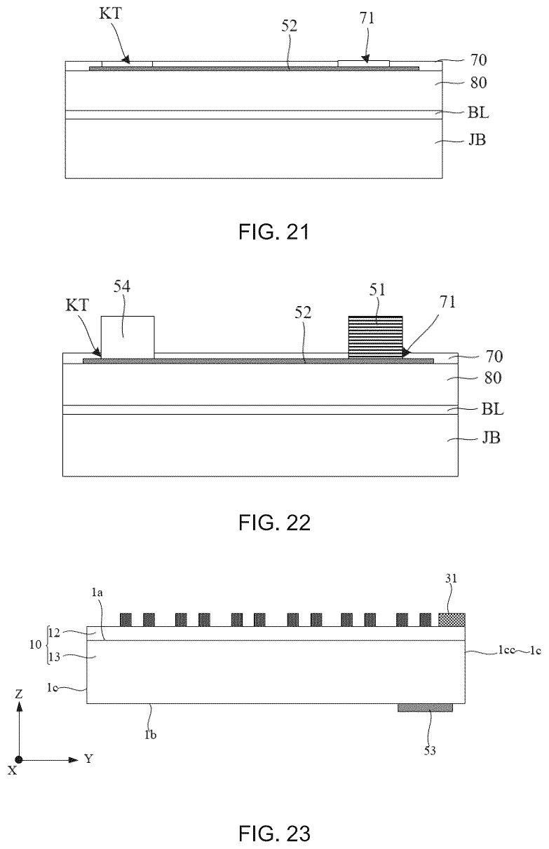

For example, referring to FIGS. 18 to 22, a second insulating layer 80 is formed on the first substrate JB. The plurality of main body portions 52 are formed on the second insulating layer 80. A first insulating layer 70 is formed on a side of the plurality of main body portions 52 away from the second insulating layer 80, so that the first insulating layer 70 covers the plurality of main body portions 52. A plurality of second openings KT and a plurality of first openings 71 exposing the plurality of main body portions 52 are formed in the first insulating layer 70. A plurality of second connection portions 51 are formed in the plurality of first openings 71, and the plurality of main body portions 52 are connected to the plurality of second connection portions 51. A plurality of third connection portions 54 are formed in the plurality of second openings KT, and the plurality of main body portions 52 are connected to the plurality of third connection portions 54. Thus, the connection lines with the first substrate JB are formed.

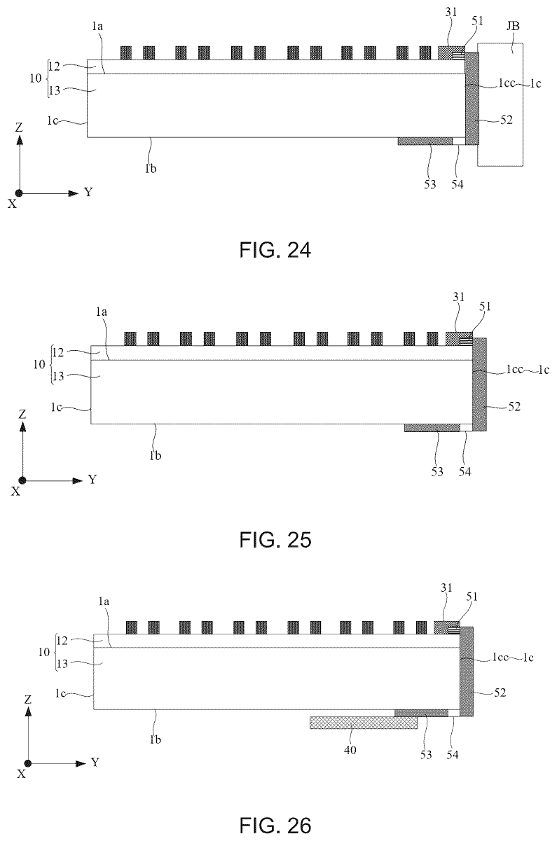

Referring to FIGS. 23 to 26, a plurality of fan-out lines 53 are formed on the second main surface 1b. The above main body portions 52 with the first substrate JB are attached to the selected side surface 1cc, so that the first connection portions 31 are connected to the second connection portions 51, and the plurality of fan-out lines 53 are connected to the plurality of third connection portions 54. The first substrate JB is removed. The circuit board 40 is bonded to ends of the plurality of fan-out lines 53 away from the plurality of third connection portions 54.

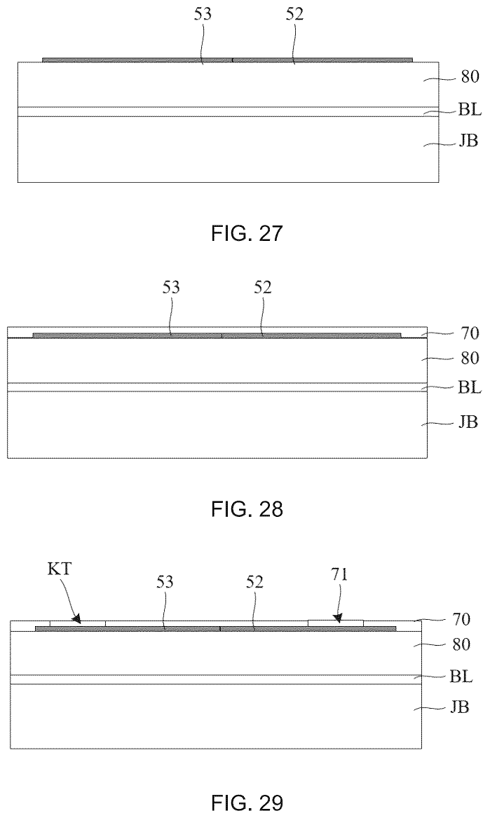

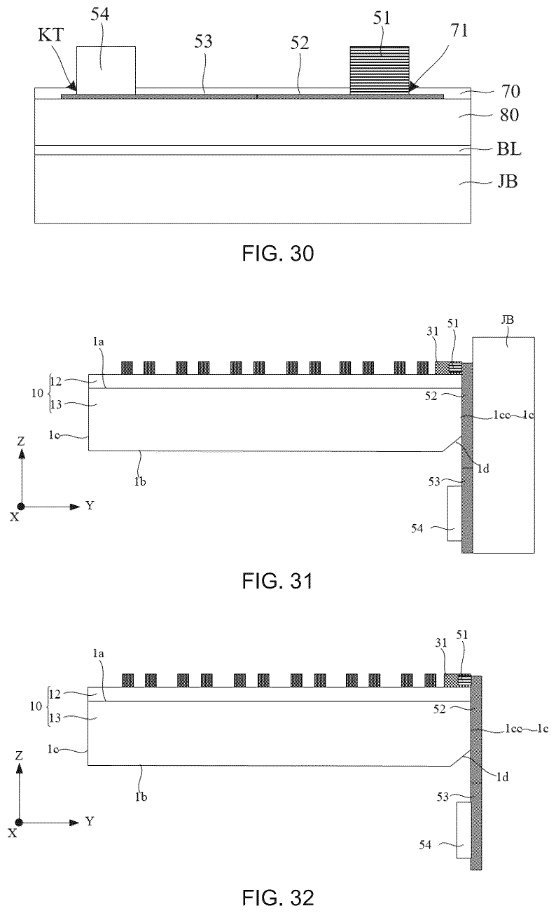

In some examples, referring to FIGS. 27 to 30, the plurality of main body portions 52 and a plurality of fan-out lines 53 are formed on the first substrate JB, for example, the plurality of fan-out lines 53 are formed on the second insulating layer 80. The plurality of fan-out lines 53 are connected to the plurality of main body portions 52. The plurality of third connection portions 54 are formed in the plurality of second openings KT, and the plurality of main body portions 52 are connected to the plurality of third connection portions 54.

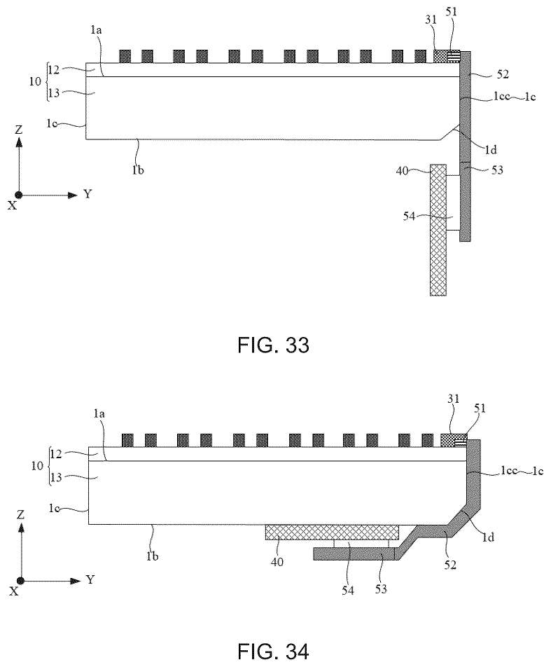

Referring to FIGS. 31 to 34, the above main body portions 52 with the first substrate JB are attached to the selected side surface 1cc, so that the first connection portions 31 are connected to the second connection portions 51. The first substrate JB is removed. The circuit board 40 is bonded to the plurality of third connection portions 54. The main body portions 52 are also attached to the first transition surface 1d and a part of the second main surface 1b, and the circuit board 40 is attached to the second main surface 1b.

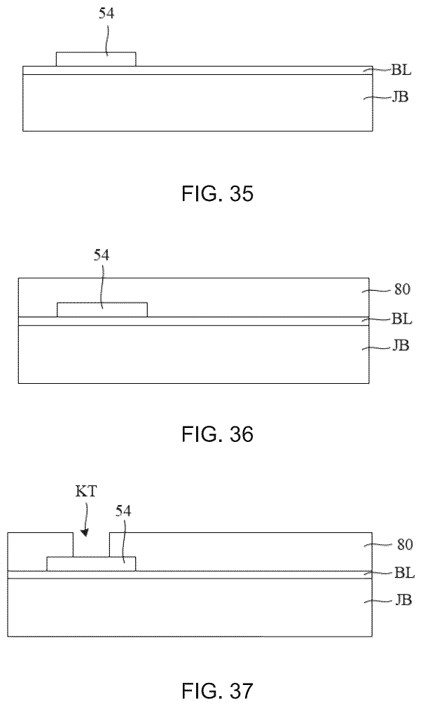

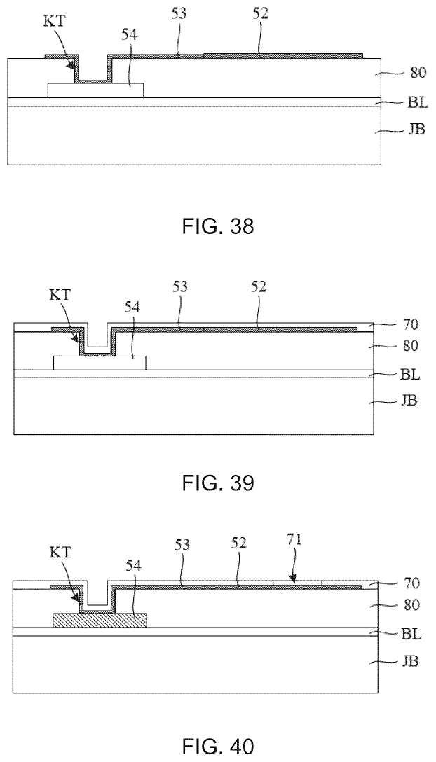

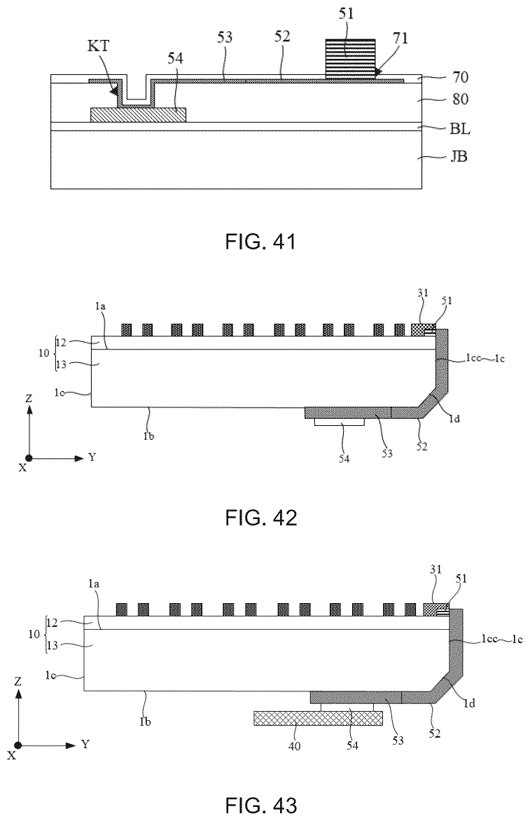

As another example, referring to FIGS. 35 to 41, a plurality of third connection portions 54 are formed on the first substrate JB. A second insulating layer 80 is formed on the first substrate JB, and the second insulating layer 80 covers the plurality of third connection portions 54. A plurality of second openings KT exposing the plurality of third connection portions 54 are formed in the second insulating layer 80. A plurality of main body portions 52 are formed on the second insulating layer 80, a plurality of fan-out lines 53 are formed in the plurality of second openings KT, and the plurality of main body portions 52 are connected to the plurality of third fan-out lines 53. A first insulating layer 70 is formed on a side of the plurality of main body portions 52 away from the second insulating layer 80, so that the first insulating layer 70 covers the plurality of main body portions 52. A plurality of first openings 71 are formed in the first insulating layer 70, and any first opening 71 exposes a main body portion 52. A plurality of second connection portions 51 are formed in the plurality of first openings 71, and the plurality of main body portions 52 are connected to the plurality of second connection portions 51.

In some examples, the plurality of main body portions 52 and a plurality of fan-out lines 53 are formed on the first substrate JB, for example, the plurality of fan-out lines 53 are formed on the second insulating layer 80. The plurality of fan-out lines 53 are connected to the plurality of main body portions 52. In this case, the plurality of fan-out lines 53 are also formed in the plurality of second openings KT, and the plurality of fan-out lines 53 are connected to the plurality of third connection portions 54.

The above main body portions 52 with the first substrate JB are attached to the selected side surface 1cc, so that the first connection portions 31 are connected to the second connection portions 51. Referring to FIGS. 42 and 43, the first substrate JB is removed. The main body portions 52 are attached to the first transition surface 1d and a part of the second main surface 1b. The circuit board 40 is bonded to the plurality of third connection portions 54.

In some examples, referring to FIGS. 17 to 23, before forming the plurality of main body portions 52 on the first substrate JB, the method further includes: forming a peelable layer BL on the first substrate JB. The main body portions 52 are formed on the peelable layer BL. For example, the second insulating layer 80 is formed on the peelable layer BL; and the main body portions 52 are formed on the second insulating layer 80.

Removing the first substrate JB includes: peeling off the peelable layer BL. As a result, a whole of the peelable layer BL and the first substrate JB is separated from the main body portions 52 (or the second insulating layer 80). For example, viscosity of a surface of the peelable layer BL proximate to the main body portions 52 is smaller than viscosity of another surface of the peelable layer BL proximate to the first substrate JB. During peeling, the peelable layer BL may be peeled off from the main body portions 52 (or the second insulating layer 80), so as to prevent the peelable layer BL from being peeled off from the first substrate JB. As another example, laser lift-off technology is used to separate the peelable layer BL from the second insulating layer 80, that is, the peelable layer BL (e.g., the material is gallium nitride) is decomposed by laser energy, thereby realizing the separation between the second insulating layer 80 and the first substrate JB. In this case, the second insulation layer 80 plays a role in isolating laser, and may prevent an influence of the laser on the main body portions 52 or the fan-out lines 53, and the backplane 10.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a backplane having a first main surface and a second main surface that are opposite, and at least one selected side surface located between the first main surface and the second main surface; the at least one selected side surface being connected to and perpendicular to the first main surface;
a plurality of light-emitting devices disposed on the first main surface;
a plurality of first connection portions disposed on the first main surface, wherein multiple first connection portions in the plurality of first connection portions are arranged side by side in an extending direction of a selected side surface and proximate to the selected side surface; the extending direction of the selected side surface is parallel to the first main surface;
a circuit board located on a side of the second main surface away from the first main surface; and
a plurality of connection lines, wherein multiple connection lines in the plurality of connection lines are arranged at intervals in the extend direction of the selected side surface the plurality of connection lines are connected between the plurality of first connection portions and the circuit board, and the plurality of connection lines are attached to the at least one selected side surface.

2. The display panel according to claim 1, wherein
the backplane further has a first transition surface; the first transition surface is connected between the selected side surface and the second main surface; a tangent plane of the first transition surface and the selected side surface have an obtuse angle therebetween, and the tangent plane of the first transition surface and the second main surface have an obtuse angle therebetween.

3. The display panel according to claim 1, wherein
the connection lines each include a main body portion and a second connection portion; the main body portion is at least attached to the selected side surface; the second connection portion is disposed on a side of a portion of the main body portion located on a side of the first main surface away from the second main surface; and the second connection portion is connected to a first connection portion.

4. The display panel according to claim 3, wherein
the second connection portion and the first connection portion are eutectic bonded.

5. The display panel according to claim 3, wherein
the main body portion is further attached to the second main surface.

6. The display panel according to claim 3, wherein
a thickness ratio of any two positions of the main body portion is in a range of 0.9 to 1.1, inclusive.

7. The display panel according to claim 3, wherein the connection lines each further include:
a third connection portion disposed on a side of a portion of the main body portion located on a side of the second main surface away from the first main surface.

8. The display panel according to claim 7, wherein
the third connection portion is connected to the circuit board.

9. The display panel according to claim 7, further comprising:
a first insulating layer and a second insulating layer that are disposed sequentially, wherein the main body portion is located between the first insulating layer and the second insulating layer; the first insulating layer has first openings each exposing the main body portion, and the second connection portion passes through a first opening to be connected to the main body portion.

10. The display panel according to claim 9, wherein
the first insulating layer or the second insulating layer has second openings each exposing the main body portion, and the third connection portion passes through a second opening to be connected to the main body portion.

11. A method for manufacturing a display panel, comprising:
providing a backplane, wherein the backplane has a first main surface and a second main surface that are opposite, and at least one selected side surface located between the first main surface and the second main surface; the at least one selected side surface is connected to and perpendicular to the first main surface;
forming a plurality of first connection portions on the first main surface, wherein multiple first connection portions in the plurality of first connection portions are arranged side by side in an extending direction of a selected side surface and proximate to the selected side surface; the extending direction of the selected side surface is parallel to the first main surface;
forming a plurality of light-emitting devices on the first main surface;
providing a circuit board on a side of the second main surface away from the first main surface; and
attaching a plurality of connection lines to the at least one selected side surface, wherein multiple connection lines in the plurality of connection lines are arranged at intervals in the extending direction of the selected side surface, and the plurality of connection lines are connected between the plurality of first connection portions and the circuit board.

12. The method for manufacturing the display panel according to claim 11, wherein
before attaching the plurality of connection lines to the at least one selected side surface, the method further comprises:
forming a plurality of main body portions on a first substrate; and
forming a plurality of second connection portions, the plurality of second connection portions being connected to the plurality of main body portions; and
attaching the plurality of connection lines to the at least one selected side surface, includes:
attaching surfaces of the plurality of main body portions away from the first substrate on the selected side surface, and the plurality of first connection portions being connected to the plurality of second connection portions; and
removing the first substrate.

13. The method for manufacturing the display panel according to claim 12, wherein
before forming the plurality of main body portions on the first substrate, the method further comprises:
forming a second insulating layer on the first substrate;
after forming the plurality of main body portions on the first substrate, and before forming the second connection portions, the method further comprises:
forming a first insulating layer on a side of the plurality of main body portions away from the substrate; and
forming a plurality of first openings in the first insulating layer exposing the plurality of main body portions; and
forming the second connection portions, includes:
forming the plurality of second connection portions in the plurality of first openings.

14. The method for manufacturing the display panel according to claim 13, wherein
before forming the second insulating layer on the first substrate, the method further comprises:
forming a plurality of third connection portions on the first substrate;
after forming the second insulating layer on the first substrate, and before forming the first insulating layer on the side of the plurality of main body portions away from the second insulating layer, the method further comprises:
forming a plurality of second openings in the second insulating layer exposing the plurality of third connection portions; and
forming the plurality of main body portions on the first substrate, includes:
forming the plurality of main body portions on the second insulating layer and in the plurality of second openings exposing the plurality of third connection portions, the plurality of main body portions being connected to the plurality of third connection portions.

15. The method for manufacturing the display panel according to claim 13, wherein
after forming the plurality of main body portions on the first substrate, and before forming the second connection portions, the method further comprises:
forming a plurality of second openings in the first insulating layer exposing the plurality of main body portions; and
after forming the plurality of second openings, the method further comprises:
forming a plurality of third connection portions in the plurality of second openings, the plurality of main body portions being connected to the plurality of third connection portions.

16. The method for manufacturing the display panel according to claim 15, wherein
before providing the circuit board on the side of the second main surface away from the first main surface, the method further comprises:
forming a plurality of fan-out lines on the second main surface; the plurality of fan-out lines being connected to the plurality of third connection portions; and
providing the circuit board on the side of the second main surface away from the first main surface, includes:
bonding the circuit board to ends of the plurality of fan-out lines away from the plurality of third connection portions.

17. The method for manufacturing the display panel according to claim 12, wherein
before forming the plurality of main body portions on the first substrate, the method further comprises:
forming a peelable layer on the first substrate; and
removing the first substrate includes:
peeling off the peelable layer.

18. A display apparatus, comprising:
the display panel according to claim 1.

19. The display panel according to claim 3, wherein
a dimension of the first connection portion in a second direction is greater than or equal to 5 μm, the second direction is a thickness direction of the backplane; and
a dimension of the second connection portion in a third direction is in a range of 8 μm to 12 μm, inclusive, the third direction is a direction perpendicular to the selected side surface.

20. The display panel according to claim 7, further comprising a plurality of fan-out lines disposed on the second main surface, wherein the plurality of fan-out lines are connected between a plurality of third connection portions and the circuit board.
